(19) United States
(12) Patent Application Publication
(10) Pub. No.: US 2025/0301864 A1
(43) Pub. Date: Sep. 25, 2025

(54) DISPLAY PANEL, MANUFACTURING METHOD THEREOF, AND DISPLAY APPARATUS

(71) Applicant: Wuhan Tianma Microelectronics Co., Ltd. Shanghai Branch, Shanghai (CN)

(72) Inventor: Shuyang YU, Shanghai (CN)

(73) Assignee: Wuhan Tianma Microelectronics Co., Ltd. Shanghai Branch, Shanghai (CN)

(21) Appl. No.: 19/233,385

(22) Filed: Jun. 10, 2025

(30) Foreign Application Priority Data
Dec. 20, 2024 (CN) 202411899312.0

(51) Int. Cl. H10K 59/126; H10K 59/12; H10K 59/122

(52) U.S. Cl. CPC H10K 59/126; H10K 59/1201; H10K 59/122

(57) ABSTRACT

Provided are a display panel, a manufacturing method thereof, and a display apparatus. The display panel includes: a substrate; a pixel defining layer located on one side of the substrate and including pixel defining structures and pixel openings surrounded by them; and light-emitting devices located on one side of the substrate and each being at least partially located within corresponding pixel openings and including a light-emitting common layer located on one side of the pixel defining layer away from the substrate; where a surface of each pixel defining structure includes a first sidewall each surrounding one corresponding pixel opening and a first top surface away from the substrate and connected to the first top surface, and each pixel defining structure further includes blocking structures located on at least part of the first sidewall. The display panel can solve the problem of sub-pixel ghosting.

### CROSS-REFERENCE TO RELATED APPLICATION

The present disclosure claims priority to Chinese Patent Application No. 202411899312.0, filed on Dec. 20, 2024, the content of which is incorporated herein by reference in its entirety.

### TECHNICAL FIELD

The present disclosure relates to the field of display technologies, and in particular, to a display panel, a manufacturing method thereof, and a display apparatus.

### BACKGROUND

With the continuous development of display technologies, organic light-emitting diode (OLED) display apparatuses have been widely used in multiple fields such as flat panel display, flexible display, in-vehicle display, solid-state lighting and the like due to their advantages such as wide color gamut, high contrast ratio, energy conservation, and foldability and the like.

### SUMMARY

Based on this, it is necessary to provide a display panel, a manufacturing method thereof, and a display apparatus, which aim to solve the problem of sub-pixel ghosting in the display panel in the related art.

In a first aspect, an embodiment of the present disclosure provides a display panel including: a substrate; a pixel defining layer located on one side of the substrate, the pixel defining layer including pixel defining structures and a plurality of pixel openings surrounded by the pixel defining structures; and a plurality of light-emitting devices located on one side of the substrate, each of the light-emitting devices being at least partially located within corresponding pixel openings of the plurality of pixel openings, each of the light-emitting devices including a light-emitting common layer located on one side of the pixel defining layer away from the substrate; where a surface of each of the pixel defining structures includes a first sidewall surrounding one corresponding pixel opening and a first top surface away from the substrate, the first sidewall is connected to the first top surface, and each of the pixel defining structures further includes a plurality of blocking structures located on at least part of the first sidewall.

In a second aspect, an embodiment of the present disclosure further provides a display apparatus including the display panel provided in the first aspect.

In a third aspect, an embodiment of the present disclosure further provides a manufacturing method of a display panel including steps of: S100, providing a substrate; S200, forming a plurality of first electrodes on one side of the substrate; S300, forming a first photoresist layer on one side of the first electrodes away from the substrate, and patterning the first photoresist layer through an exposure and development process to form first intermediate structures, the first intermediate structures each including a first lower part and a first upper part stacked in sequence on a corresponding first electrode of the first electrodes, an orthographic projection of the first lower part on the substrate being within an orthographic projection of the first upper part on the substrate, and the orthographic projection of the first lower part on the substrate being within an orthographic projection of the corresponding first electrode on the substrate; S400, forming a first defining material layer on one side of the first electrodes away from the substrate, in a direction perpendicular to a plane of the substrate, a thickness of the first defining material layer being greater than a thickness of each of the first intermediate structures, and the first defining material layer filling a gap between two adjacent first intermediate structures; S500, patterning the first defining material layer through an exposure and development process to form a plurality of first preset structures, the first preset structures each including a second lower part located between two adjacent first intermediate structures and a second upper part located on one side of the second lower part and one side of one corresponding first intermediate structure of the first intermediate structures away from the substrate, the second upper part being connected to one corresponding second lower part, in a direction parallel to the plane of the substrate, a width of the second upper part being greater than a distance between two adjacent first upper parts, the second upper part including protrusions protruding in the direction parallel to the plane of the substrate relative to a sidewall of the corresponding second lower part, and the protrusions being provided on surfaces of two adjacent first intermediate structures on one side away from the substrate; S600, forming a second photoresist layer on one side of the first intermediate structures and one side of the first preset structures away from the substrate, a material of the second photoresist layer being different from a material of the first photoresist layer, and patterning the second photoresist layer through an exposure and development process to form second intermediate structures, in the direction perpendicular to the plane of the substrate, the second intermediate structures each being stacked with one corresponding first intermediate structure, and the second intermediate structures each covering two opposite protrusions of two adjacent first preset structures; S700, forming a second defining material layer on one side of the first intermediate structures away from the substrate, in the direction perpendicular to the plane of the substrate, a thickness of the second defining material layer being less than or equal to a height of each of the second intermediate structures, the second defining material layer including a plurality of second preset structures, and the second preset structures each being located between two adjacent second intermediate structures; and S800, removing the first intermediate structures and the second intermediate structures to form pixel defining structures by the first preset structures and the second preset structures.

In the embodiments of the present disclosure, by providing, on the first sidewall of the pixel defining structure which surrounds the pixel opening, the plurality of blocking structures located on at least part of the first sidewall, the light-emitting common layer such as a hole injection layer and the like is broken at the blocking structures, blocking the path of the lateral flow of charges, or the light-emitting common layer such as a hole injection layer and the like is thinned at the blocking structures, increasing the resistance of the lateral flow of charges. Thus, the problem of sub-pixel ghosting can be avoided or alleviated, thereby improving the display quality of pure color images and low gray scale images.

### BRIEF DESCRIPTION OF DRAWINGS

To more clearly illustrate the technical solutions in the embodiments of the present disclosure or in the traditional technology, the drawings required to be used in the description of the embodiments or the conventional technology will be introduced below. The drawings in the following description are only some embodiments of the present disclosure, and for those of ordinary skill in the art, other drawings can be obtained from these drawings.

FIG. 1 is an overall schematic diagram of a display panel provided by some embodiments of the present disclosure;

FIG. 2 is a first top view schematic diagram of a display panel provided by some embodiments of the present disclosure;

FIG. 3 is a schematic diagram of a first cross-sectional structure of a display panel provided by some embodiments of the present disclosure;

FIG. 4 is a schematic diagram of a second cross-sectional structure of a display panel provided by some embodiments of the present disclosure;

FIG. 5 is a schematic diagram of a third cross-sectional structure of a display panel provided by some embodiments of the present disclosure;

FIG. 6 is a second top view schematic diagram of a display panel provided by some embodiments of the present disclosure;

FIG. 7 is a third top view schematic diagram of a display panel provided by some embodiments of the present disclosure;

FIG. 8 is a fourth top view schematic diagram of a display panel provided by some embodiments of the present disclosure;

FIG. 9 is a schematic diagram of a fourth cross-sectional structure of a display panel provided by some embodiments of the present disclosure;

FIG. 10 is a schematic diagram of a display apparatus provided in some embodiments of the present disclosure;

FIG. 11 is a schematic diagram of process steps of a manufacturing method of a display panel provided by some embodiments of the present disclosure;

FIG. 12 is a schematic diagram of a first intermediate process of a manufacturing method of a display panel provided by some embodiments of the present disclosure;

FIG. 13 is a schematic diagram of a second intermediate process of a manufacturing method of a display panel provided by some embodiments of the present disclosure;

FIG. 14 is a schematic diagram of a third intermediate process of a manufacturing method of a display panel provided by some embodiments of the present disclosure;

FIG. 15 is a schematic diagram of a fourth intermediate process of a manufacturing method of a display panel provided by some embodiments of the present disclosure;

FIG. 16 is a schematic diagram of a fifth intermediate process of a manufacturing method of a display panel provided by some embodiments of the present disclosure;

FIG. 17 is a schematic diagram of a sixth intermediate process of a manufacturing method of a display panel provided by some embodiments of the present disclosure;

FIG. 18 is a schematic diagram of a seventh intermediate process of a manufacturing method of a display panel provided by some embodiments of the present disclosure;

FIG. 19 is a schematic diagram of an eighth intermediate process of a manufacturing method of a display panel provided by some embodiments of the present disclosure;

FIG. 20 is a schematic diagram of a ninth intermediate process of a manufacturing method of a display panel provided by some embodiments of the present disclosure; and

FIG. 21 is a schematic diagram of a tenth intermediate process of a manufacturing method of a display panel provided by some embodiments of the present disclosure.

### DESCRIPTION OF EXAMPLES

To facilitate the understanding of the present disclosure, the present disclosure will be described more comprehensively below with reference to the related drawings. Preferred embodiments of the present disclosure are shown in the drawings. However, the present disclosure can be implemented in many different forms and is not limited to the embodiments described herein. Rather, the purpose of providing these embodiments is to make the understanding of the disclosure of the present disclosure more thorough and comprehensive.

Unless otherwise defined, all technical and scientific terms used herein have the same meaning as commonly understood by one of ordinary skill in the art to which the present disclosure belongs. The terms used herein in the specification of the present disclosure are only for the purpose of describing specific embodiments and are not intended to limit the present disclosure. The term “and/or” used herein includes any and all combinations of one or more of the related listed items.

When describing the positional relationship, unless otherwise specified, when an element such as a layer, a film, or a substrate is referred to as being “on” another element, it can be directly on the other element or an intermediate element can also exist. Further, when a layer is referred to as being “under” another layer, it can be directly below or one or more intermediate elements can also exist. It can also be understood that when a layer is referred to as being “between” two layers, it can be the only layer between the two layers, or one or more intermediate elements can also exist.

When using the terms “including”, “having” and “comprising” recited herein, another component can be added unless an explicit limiting term for example “only”, “consisting of . . . ” or the like is used. Unless otherwise mentioned, the singular form of a term can include the plural form and should not be understood as having a quantity of one.

It should be understood that although the terms “first”, “second”, etc. can be used herein to describe various elements, these elements should not be limited by these terms. These terms are only used to distinguish one element from another. For example, without departing from the scope of the present disclosure, the first element can be referred to as the second element, and similarly, the second element can be referred to as the first element.

It should also be understood that when interpreting an element, although not explicitly described, the element should be interpreted as including an error range, and the error range should be within an acceptable deviation range of a specific value that can be accepted by those of skill in the art. For example, “approximately”, “about” or “substantially” can mean within one or more standard deviations, which is not limited herein.

In addition, in the specification, the phrase “planar distribution schematic diagram” refers to a drawing when a target part is viewed from above, and the phrase “cross-sectional schematic diagram” refers to a drawing when a cross-section obtained by vertically cutting a target part is viewed from the side.

In addition, the drawings are not drawn to a scale of 1:1, and the relative sizes of the various elements are only drawn by way of example in the drawings and not necessarily to a true scale.

In the related art, there is a problem of sub-pixel ghosting in the display panel. The applicant found that the reason for the above phenomenon is that: there is a difference in the operating voltages of sub-pixels (light-emitting devices) of different colors, when a sub-pixel (light-emitting device) with a higher operating voltage is turned on by applying a voltage, most of the current will flow to that sub-pixel (light-emitting device) with the higher operating voltage; since a light-emitting common layer such as a hole injection layer and the like has higher conductivity, a small part of the current will also flow to a sub-pixel (light-emitting device) with a lower operating voltage through the light-emitting common layer such as a hole injection layer and the like, that is, a lateral leakage current occurs, and this lateral leakage current leads to sub-pixel ghosting, resulting in the phenomena of impure monochromatic display and color distortion of low gray scale images.

In view of the above technical problem, the applicant has studied and found that by providing, on the first sidewalls of pixel defining structures which each surrounds one corresponding pixel opening, a plurality of blocking structures located on at least part of the first sidewalls, the light-emitting common layer such as a hole injection layer and the like is broken at the blocking structures, blocking the path of the lateral flow of charges, or the light-emitting common layer such as a hole injection layer and the like is thinned at the blocking structures, increasing the resistance of the lateral flow of charges. Thus, the problem of sub-pixel ghosting can be avoided or alleviated, thereby improving the display quality of pure color images and low gray scale images.

The above is the core idea of the present disclosure. The technical solutions in the embodiments of the present disclosure are clearly and completely described below in conjunction with the drawings in the embodiments of the present disclosure. Based on the embodiments in the present disclosure, all other embodiments obtained by those of ordinary skill in the art shall fall within the protection scope of the present disclosure.

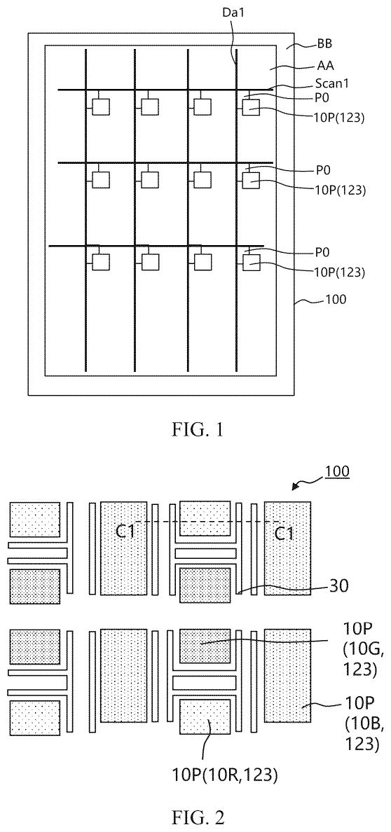

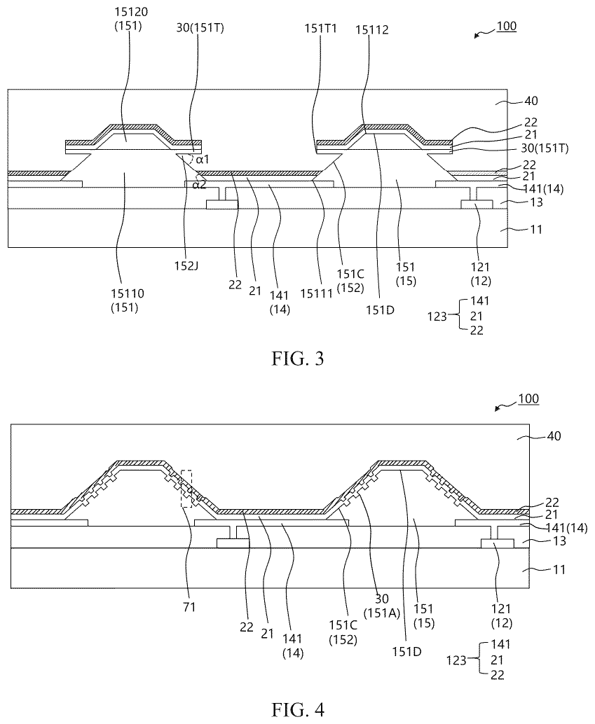

FIG. 1 is an overall schematic diagram of a display panel provided by some embodiments of the present disclosure, FIG. 2 is a first top view schematic diagram of a display panel provided by some embodiments of the present disclosure, and FIG. 3 is a schematic diagram of a first cross-sectional structure of a display panel provided by some embodiments of the present disclosure. FIG. 2 is a partial enlarged schematic diagram of FIG. 1. FIG. 3 is a cross-sectional structure at a dotted line C1-C1 in FIG. 2.

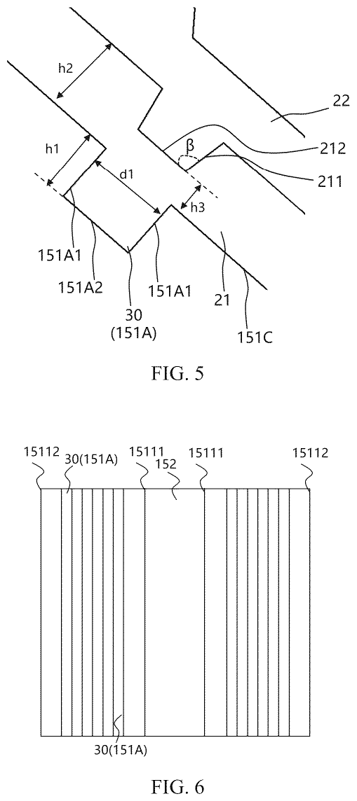

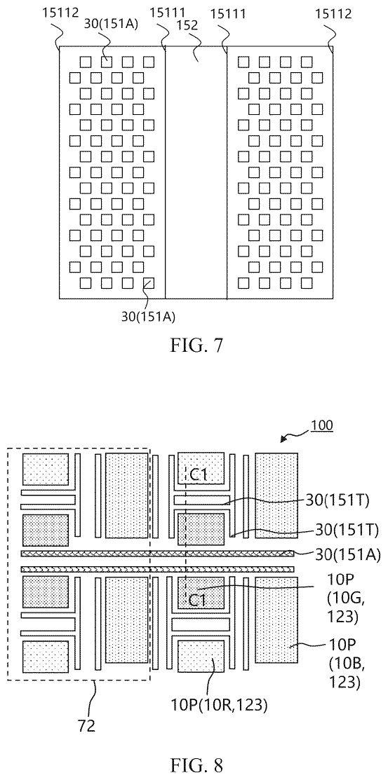

FIG. 4 is a schematic diagram of a second cross-sectional structure of a display panel provided by some embodiments of the present disclosure, FIG. 5 is a schematic diagram of a third cross-sectional structure of a display panel provided by some embodiments of the present disclosure, FIG. 6 is a second top view schematic diagram of a display panel provided by some embodiments of the present disclosure, and FIG. 7 is a third top view schematic diagram of a display panel provided by some embodiments of the present disclosure. FIG. 4 is a cross-sectional structure at the dotted line C1-C1 in FIG. 2. FIG. 5 is an enlarged schematic diagram at a dotted frame 71 in FIG. 4. FIGS. 6 and 7 are partial enlarged schematic diagrams of FIG. 1.

FIG. 8 is a fourth top view schematic diagram of a display panel provided by some embodiments of the present disclosure, and FIG. 9 is a schematic diagram of a fourth cross-sectional structure of a display panel provided by some embodiments of the present disclosure. FIG. 8 is a partial enlarged schematic diagram of FIG. 1. FIG. 9 is a cross-sectional structure at a dotted line C1-C1 in FIG. 8.

In a first aspect, referring to FIGS. 1 to 9, the present disclosure provides a display panel 100. The display panel 100 includes a substrate 11, a pixel defining layer 15, and a plurality of light-emitting devices 123. The pixel defining layer 15 is located on one side of the substrate 11, and includes pixel defining structures 151 and a plurality of pixel openings 152 surrounded by the pixel defining structures 151. The plurality of light-emitting devices 123 are located on one side of the substrate 11, and each of the light-emitting devices 123 is at least partially located within corresponding pixel openings 152 and includes a light-emitting common layer 21 located on one side of the pixel defining layer 15 away from the substrate 11. A surface of each of the pixel defining structures 151 includes a first sidewall 151C each surrounding one corresponding pixel opening 152 and a first top surface 151D on one side away from the substrate 11, the first sidewall 151C are connected to the first top surface 151D, and each of the pixel defining structures 151 further includes a plurality of blocking structures 30 located on at least part of the first sidewall 151C.

Exemplarily, as shown in FIG. 1 for illustration, where FIG. 2 is a partial enlarged schematic diagram of FIG. 1, the display panel 100 is an OLED panel. The display panel 100 can include a display area AA and a non-display area BB surrounding the display area AA. A plurality of sub-pixels 10P are provided in the display area AA. The sub-pixels 10P include sub-pixels of different colors. The sub-pixels of different colors include light-emitting devices of different colors. For example, a red sub-pixel includes a red light-emitting device 10R, a green sub-pixel includes a green light-emitting device 10G, and a blue sub-pixel includes a blue light-emitting device 10B. In FIG. 2, the display panel 100 further includes pixel driving circuits P0, a scan signal line Scan1, and a data signal line Dal provided in the display area AA. The scan signal line Scan1 and the data signal line Dal control a corresponding pixel driving circuit P0, and the pixel driving circuit P0 drives a light-emitting device 123 in a corresponding sub-pixel 10P to emit light.

Exemplarily, a structure of the light-emitting device of the OLED panel generally includes an anode, auxiliary functional layers (for example a hole transport layer, an electron transport layer, an electron injection layer, etc.), a light-emitting layer, and a cathode which correspond to each sub-pixel 10P. When a voltage is applied to the anode and the cathode, holes and electrons are respectively transported and moved to the light-emitting layer, and the two are recombined in the light-emitting layer to form excitons; the excitons migrate under the action of an electric field, transfer energy to a light-emitting material, and excite electrons in the light-emitting material to transition from a ground state to an excited state. The energy of the excited state generates photons through radiative deactivation to release light energy.

Exemplarily, the substrate 11 can be a glass substrate or a flexible substrate. For example, the material of the substrate 11 includes polyimide, which is not limited herein.

Exemplarily, a film layer structure of the display panel 100 can include a first conductive layer 12, a first insulating layer 13, a first electrode layer 14, a pixel defining layer 15, a light-emitting common layer 21, second electrodes 22, and an encapsulation layer 40 stacked in sequence. However, the film layer structure of the display panel 100 is not limited to this.

Exemplarily, the first conductive layer 12 includes a plurality of first conductive portions 121. Each of the first conductive portions 121 can be a source or drain of a thin-film transistor in the driving circuit, or each of the first conductive portions 121 can be electrically connected to a source or drain of a thin-film transistor in the driving circuit.

Exemplarily, the first electrode layer 14 includes a plurality of first electrodes 141 arranged at intervals or in an array.

Exemplarily, each of the first electrodes 141 can be one of an anode and a cathode, and each of the second electrodes 22 can be the other of the anode and the cathode. Each of the first electrodes 141 is exemplified as an anode in the present disclosure.

Exemplarily, the light-emitting common layer 21 can include one or more of a light-emitting layer EML, a hole injection layer HIL, a hole transport layer HTL, an electron injection layer EIL, an electron transport layer ETL, a hole blocking layer HBL, and an electron blocking layer EBL.

Exemplarily, the surface of each of the pixel defining structures 151 includes the first sidewall 151C surrounding one corresponding pixel opening 152 and the first top surface 151D on one side away from the substrate 11, and the first sidewall 151C is connected to the first top surface 151D. For example, a cross-section of the pixel defining structure 151 is trapezoidal, waists of the trapezoid are the first sidewall 151C, and the upper base of the trapezoid away from the substrate 11 is the first top surface 151D.

Exemplarily, it should be noted that a minimum thickness of the light-emitting common layer 21 at the blocking structures 30 is less than a minimum thickness of the light-emitting common layer 21 on an adjacent first top surface 151D, which can alleviate or avoid the lateral flow of charges.

In the embodiments of the present disclosure, by providing, on the first sidewall 151C of the pixel defining structure 151 which surrounds one corresponding pixel opening 152, the plurality of blocking structures 30 located on at least part of the first sidewall 151C, the light-emitting common layer 21 such as a hole injection layer and the like is broken at the blocking structures 30, blocking the path of the lateral flow of charges, or the light-emitting common layer 21 such as a hole injection layer and the like is thinned at the blocking structures 30, increasing the resistance of the lateral flow of charges. Thus, the problem of sub-pixel ghosting can be avoided or alleviated, thereby improving the display quality of pure color images and low gray scale images.

In some implementations, the plurality of blocking structures 30 include at least one of a plurality of protrusions 151T and a plurality of grooves 151A located on the first sidewall 151C.

Exemplarily, as shown in FIGS. 2 and 3, the plurality of blocking structures 30 include the plurality of protrusions 151T located on the first sidewall 151C. The light-emitting common layer 21 such as a hole injection layer and the like is disconnected at the protrusions 151T, blocking the path of the lateral flow of charges. Thus, the problem of sub-pixel ghosting can be avoided or alleviated, thereby improving the display quality of pure color images and low gray scale images.

Exemplarily, as shown in FIGS. 2, and 4 to 7, the plurality of blocking structures 30 include the plurality of grooves 151A located on the first sidewall 151C. The light-emitting common layer 21 such as a hole injection layer and the like is thinned at the grooves 151A, increasing the resistance of the lateral flow of charges. Thus, the problem of sub-pixel ghosting can be avoided or alleviated, thereby improving the display quality of pure color images and low gray scale images.

Exemplarily, as shown in FIGS. 8 and 9, the plurality of blocking structures 30 include the plurality of protrusions 151T and the plurality of grooves 151A located on the first sidewall 151C, which has the improvement effects of both the protrusions 151T and the grooves 151A.

In some implementations, as shown in FIGS. 2 and 3, the plurality of blocking structures 30 include the plurality of protrusions 151T located on the first sidewall 151C, and a first gap 152J is formed between a surface of each of the protrusions 151T close to the substrate 11 and the first sidewall 151C.

Exemplarily, the plurality of blocking structures 30 include the plurality of protrusions 151T located on the first sidewall 151C. Each of the protrusions 151T is suspended to form the first gap 152J, and the first gap 152J causes the light-emitting common layer 21 such as a hole injection layer and the like to be disconnected at the protrusion 151T.

In some implementations, as shown in FIGS. 2 and 3, at the first gap 152J, an included angle between the surface of the protrusion 151T close to the substrate 11 and the first sidewall 151C is an acute angle, and an included angle between the first sidewall 151C and a bottom surface of the pixel defining structure 151 close to the substrate 11 is an acute angle.

Exemplarily, at the first gap 152J, the included angle between the surface of the protrusion 151T close to the substrate 11 and the first sidewall 151C is a first angle α₁ which is an acute angle, to prevent the protrusion 151T from being easily broken or cracked.

Exemplarily, the included angle between one the first sidewall 151C and the bottom surface of the pixel defining structure 151 on one side close to the substrate 11 is a second angle α₂ which is an acute angle. For example, the cross-section of the pixel defining structure 151 is trapezoidal, so that the light-emitting common layer 21 is well formed on one side of the first electrodes 141 away from the substrate 11.

In some implementations, as shown in FIGS. 2 and 3, a protruding direction of the protrusion 151T is parallel to a plane of the substrate 11.

Exemplarily, the protruding direction (extending direction) of the protrusion 151T is parallel to the plane of the substrate 11, which can be easier to be manufactured (which will be further introduced in a subsequent manufacturing method of a display panel), reducing the manufacturing cost and process steps.

In some implementations, as shown in FIGS. 2 and 3, an edge of the protrusion 151T includes a first protrusion sub-edge 151T1 close to the pixel opening 152, and an edge of the first sidewall 151C includes a first sidewall sub-edge 15111 close to the substrate 11 and a second sidewall sub-edge 15112 connected to the first top surface 151D, and along a direction perpendicular to the substrate 11, an orthographic projection of the first protrusion sub-edge 151T 1 is located between an orthographic projection of the first sidewall sub-edge 15111 and an orthographic projection of the second sidewall sub-edge 15112.

Exemplarily, along a direction perpendicular to the substrate 11, the orthographic projection of the first protrusion sub-edge 151T1 is located between the orthographic projection of the first sidewall sub-edge 15111 and the orthographic projection of the second sidewall sub-edge 15112, that is, in a direction perpendicular to the plane of the substrate 11, the protrusion 151T and a bottom wall of the pixel opening 152 are not stacked or overlapped, avoiding the formation of a film layer such as the light-emitting common layer 21 and the like on the bottom wall of the pixel opening 152 from being blocked by the protrusion 151T, and ensuring the structural integrity of the light-emitting device 123.

In some implementations, as shown in FIGS. 2 and 3, in a direction perpendicular to the plane of the substrate 11, the pixel defining structure 151 includes at least a first portion 15110 located on one side of the protrusions 151T close to the substrate 11 and a second portion 15120 located on one side of the protrusions 151T away from the substrate 11, and the protrusion 151T and the first portion 15110 are an integrally formed structure.

Exemplarily, in conjunction with a manufacturing method of a display panel below, during the manufacturing process, the protrusion 151T and the first portion 15110 (the protrusion 151T and the first portion 15110 together are equivalent to a first preset structure D11) are first manufactured in the same process step, and the protrusion 151T and the first portion 15110 are an integrally formed structure, and then the manufacturing of the second portion 15120 (the second portion 15120 is equivalent to a second preset structure D21) is achieved. Such a manufacturing process has simple steps, and is easier to manufacture the protrusion 151T.

In some implementations, as shown in FIGS. 2 and 3, in a plane parallel to the plane of the substrate 11, the protrusion 151T is a non-closed structure extending around the corresponding pixel opening 152.

Exemplarily, the light-emitting common layer 21 such as a hole injection layer and the like is disconnected at the protrusions 151T, but the second electrodes 22 are also easily disconnected at the protrusions 151T. To ensure that the second electrode 22 of one light-emitting device 123 is communicated with the second electrode 22 of an adjacent light-emitting device 123, it is necessary to set each of the protrusions 151T as a non-closed structure extending around the corresponding pixel opening 152, ensuring that the second electrodes 22 are a communicated integral structure for the plurality of light-emitting devices 123, and ensuring that the part of the second electrode 22 corresponding to each of the light-emitting devices 123 can be applied with a voltage.

In some implementations, as shown in FIGS. 2 and 4 to 7, the plurality of blocking structures 30 include the plurality of grooves 151A located on the first sidewall 151C, and an opening of each of the grooves 151A faces a direction of the first sidewall 151C away from the substrate 11.

Exemplarily, the plurality of blocking structures 30 include the plurality of grooves 151A located on the first sidewall 151C, the light-emitting common layer 21 such as a hole injection layer and the like is thinned at the grooves 151A, increasing the resistance of the lateral flow of charges. Thus, the problem of sub-pixel ghosting can be avoided or alleviated, thereby improving the display quality of pure color images and low gray scale images.

Exemplarily, a thickness of the light-emitting common layer 21 at an edge of the groove 151A is a second thickness h3 (a thickness of the light-emitting common layer 21 at a sidewall of the groove 151A is the second thickness h3), and a thickness of the light-emitting common layer 21 at a portion outside two sides of the groove is equal to a first thickness h2. Due to the presence of a slope at the sidewall of the groove 151A, the second thickness h3 is reduced, so that the second thickness h3 is less than the first thickness h2, and the second thickness h3 is greater than 0.

In some implementations, as shown in FIGS. 2, 4, and 5 to 7, in a direction perpendicular to the surface where the first sidewall 151C is located, a depth of the groove 151A is a first depth h1, a thickness of the light-emitting common layer 21 is a first thickness h2, and the first depth h1 is less than the first thickness h2.

Exemplarily, the first depth h1 being less than the first thickness h2 can make the light-emitting common layer 21 thinned at the groove 151A instead of being broken at the groove 151A, avoiding the second electrode 22 from being broken or thinned at the groove 151A. In this way, a plurality of grooves 151A can be provided, and the thickness of the light-emitting common layer 21 can be reduced at a plurality of positions, thereby greatly increasing the lateral resistance of the light-emitting common layer 21, better improving sub-pixel ghosting, and at the same time, ensuring the thickness uniformity and voltage uniformity of the second electrodes 22.

Exemplarily, the first depth h1 being less than the first thickness h2 can make the light-emitting common layer 21 thinned at the groove 151A instead of being broken at the groove 151A, avoiding the second electrode 22 from being broken or thinned at the groove 151A. In this way, the groove 151A can be provided as a closed structure surrounding the light-emitting device 123 without having an impact of breaking or thinning on the second electrode 22. The light-emitting common layer 21 is thinned in all directions of the pixel opening 152, reducing the lateral leakage current from all directions of the pixel opening 152, and better improving sub-pixel ghosting.

In some implementations, as shown in FIGS. 2, 4, and 5 to 7, a ratio of the first depth h1 to the first thickness h2 ranges from 0.5 to 0.8.

Exemplarily, through verification by the applicant, when the ratio of the first depth h1 to the first thickness h2 ranges from 0.5 to 0.8, for each part of the entire display panel 100, not only can the thickness of the light-emitting common layer 21 be well reduced at the groove 151A, but also the impact on the thickness of the second electrode 22 can be well avoided. A surface formed by the light-emitting common layer 21 is relatively flat, ensuring the thickness uniformity and voltage uniformity of the second electrode 22.

In some implementations, as shown in FIGS. 2, 4, and 5 to 7, in a direction from an end of the first sidewall 151C close to the substrate 11 to an end of the first sidewalls 151C close to the first top surface 151D, a width of the groove 151A is a first width D1, and the first width D1 ranges from 200 nanometers to 500 nanometers.

Exemplarily, through verification by the applicant, on the plane of the first sidewall 151C, the width of the groove 151A is the first width D1, and the first width D1 ranges from 200 nanometers to 500 nanometers, which can not only well reduce the thickness of the light-emitting common layer 21 at the groove 151A, but also well avoid the impact on the thickness of the second electrode 22.

In some implementations, as shown in FIGS. 2, and 4 to 7, the groove 151A includes two groove sidewalls 151A1 provided opposite to each other and a groove bottom wall 151A2 connecting the two groove sidewalls 151A1 provided opposite to each other. The light-emitting common layer 21 includes a first common layer portion 211 covering the groove sidewalls 151A1 and a second common layer portion 212 covering the groove bottom wall 151A2, and an included angle between the first common layer portion 211 and the second common layer portion 212 in a direction away from the substrate 11 is greater than 110 degrees.

Exemplarily, the included angle between the first common layer portion 211 and the second common layer portion 212 in the direction away from the substrate 11 is a third angle β, which is greater than 110 degrees, and at this time, the thickness of the light-emitting common layer 21 is thinned instead of the light-emitting common layer 21 being broken. At the same time, a surface angle of the light-emitting common layer 21 has a relatively gentle transition, ensuring the thickness uniformity and voltage uniformity of the second electrode 22.

Exemplarily, by controlling that the first depth h1 is less than the first thickness h2, the ratio of the first depth h1 to the first thickness h2 ranges from 0.5 to 0.8, and the first width D1 ranges from 200 nanometers to 500 nanometers, the third angle β can be made greater than 110 degrees.

In some implementations, as shown in FIG. 6, the plurality of blocking structures 30 include the plurality of grooves 151A located on one first sidewall 151C, the plurality of grooves 151A are arranged in sequence from an end of the one first sidewall 151C close to the substrate 11 to an end of the one first sidewall 151C close to the first top surface 151D, and the grooves 151A extend around the corresponding pixel opening 152.

Exemplarily, on the plane of the one first sidewall 151C, or on the one first sidewall 151C, from the first sidewall sub-edge 15111 to the second sidewall sub-edge 15112, the plurality of grooves 151A can be sequentially provided to surround the corresponding pixel opening 152. Each of the grooves 151A can be in a strip shape, a curve shape, or an arc shape, which can thin the thickness of the light-emitting common layer 21 at a plurality of positions, better increasing the lateral resistance of the light-emitting common layer, and better alleviating the problem of sub-pixel ghosting.

In some implementations, as shown in FIG. 7, the pixel defining structure 151 includes the plurality of grooves 151A located on one first sidewall 151C, and an orthographic projection of each of the grooves 151A on a plane of the one first sidewall 151C is in a block shape. On the one first sidewall 151C, the plurality of grooves 151A are arranged in a staggered manner around the corresponding pixel opening 152.

Exemplarily, on the plane of the one first sidewall 151C, or on the one the first sidewall 151C, from the first sidewall sub-edge 15111 to the second sidewall sub-edge 15112, the plurality of grooves 151A can be provided to surround the corresponding pixel opening 152. The plurality of grooves 151A can be in a plurality of block shapes, a plurality of line segment shapes, or a plurality of spaced arc shapes. The plurality of grooves 151A are arranged in a staggered manner around the corresponding pixel opening 152, which can thin the thickness of the light-emitting common layer 21 at a plurality of staggered positions, better increasing the lateral resistance of the light-emitting common layer, and better alleviating the problem of sub-pixel ghosting.

In some implementations, as shown in FIGS. 8 and 9, at least part of the blocking structures 30 include the protrusions 151T located on the first sidewall 151C and the grooves 151A located on the first sidewall 151C, the protrusions 151T are provided on the first sidewall 151C on at least one side of at least part of the light-emitting devices 123, and the grooves 151A are provided on the first sidewall 151C on at least one side of at least part of the light-emitting devices 123.

Exemplarily, the protrusions 151T can be provided on the first sidewall 151C at one part of the display panel 100, and the grooves 151A can be provided on the first sidewall 151C at another part of the display panel 100.

Exemplarily, the protrusions 151T can be provided on the first sidewall 151C on one side of a light-emitting device 123, and the grooves 151A can be provided on the first sidewall 151C on the other side of the light-emitting device 123.

In some implementations, as shown in FIGS. 8 and 9, the protrusions 151T and the grooves 151A are provided on the first sidewall 151C around each of at least part of the light-emitting devices 123, and the protrusions 151T and the grooves 151A are located on different sides of the light-emitting device 123.

Exemplarily, by providing both the protrusions 151T and the grooves 151A, and the protrusions 151T and the grooves 151A being located on different sides of the light-emitting device 123, the protrusions 151T can better block the lateral leakage current, the grooves 151A can reduce the lateral leakage current, and at the same time, the grooves 151A can ensure that the second electrodes 22 between different light-emitting devices 123 have good electrical connection, so that sub-pixel ghosting, and the thickness uniformity and voltage uniformity of the second electrodes 22 are all well improved.

In some implementations, as shown in FIGS. 8 and 9, the plurality of light-emitting devices 123 include light-emitting devices 123 of different colors, at least part of the protrusions 151T are located between adjacent light-emitting devices 123 of different colors, and at least part of the grooves 151A are located between adjacent light-emitting devices 123 of a same color.

Exemplarily, there is a difference in the operating voltages of sub-pixels (light-emitting devices) of different colors, and a lateral leakage current is more likely to exist between two adjacent light-emitting devices 123 of different colors, or in other words, the lateral leakage current existing between two adjacent light-emitting devices 123 of different colors is larger, so the protrusions 151T are provided between the light-emitting devices 123 of different colors to block the light-emitting common layer 21, and the protrusions 151T block the lateral leakage current, which can better improve sub-pixel ghosting.

Exemplarily, as shown in FIG. 8, the plurality of light-emitting devices 123 include red light-emitting devices 10R, green light-emitting devices 10G, and blue light-emitting devices 10B. The pixel arrangement manner in FIG. 8 is referred to as a 7L arrangement. A repetition unit 72 in FIG. 8 includes two pixels, and the arrangement manner in the repetition unit 72 is: a red light-emitting device 10R, a green light-emitting device 10G, a green light-emitting device 10G, and a red light-emitting device 10R being sequentially arranged in a column direction, and a blue light-emitting device 10B being sequentially arranged in a row direction with a red light-emitting device 10R and a green light-emitting device 10G, that is, one blue light-emitting device 10B corresponds to one red light-emitting device 10R and one green light-emitting device 10G.

Exemplarily, as shown in FIG. 8, protrusions 151T are provided between the red light-emitting device 10R and the green light-emitting device 10G, protrusions 151T are provided between the red light-emitting device 10R and the blue light-emitting device 10B, and protrusions 151T are provided between the green light-emitting device 10G and the blue light-emitting device 10B, which can block the larger lateral leakage current between two adjacent light-emitting devices 123 of different colors.

Exemplarily, the operating voltages of sub-pixels (light-emitting devices) of the same color are the same, and a lateral leakage current is less likely to exist between two adjacent light-emitting devices 123 of the same color, or in other words, the lateral leakage current existing between two adjacent light-emitting devices 123 of the same color is smaller, so the grooves 151A are provided between the light-emitting devices 123 of the same color, which can reduce the lateral leakage current to a certain extent, as well as can ensure the thickness uniformity and voltage uniformity of the second electrodes.

Exemplarily, as shown in FIG. 8, grooves 151A are provided between one green light-emitting device 10G and another green light-emitting device 10G, and grooves 151A are provided between one blue light-emitting device 10B and another blue light-emitting device 10B, which can reduce the smaller lateral leakage current between two adjacent light-emitting devices 123 of the same color.

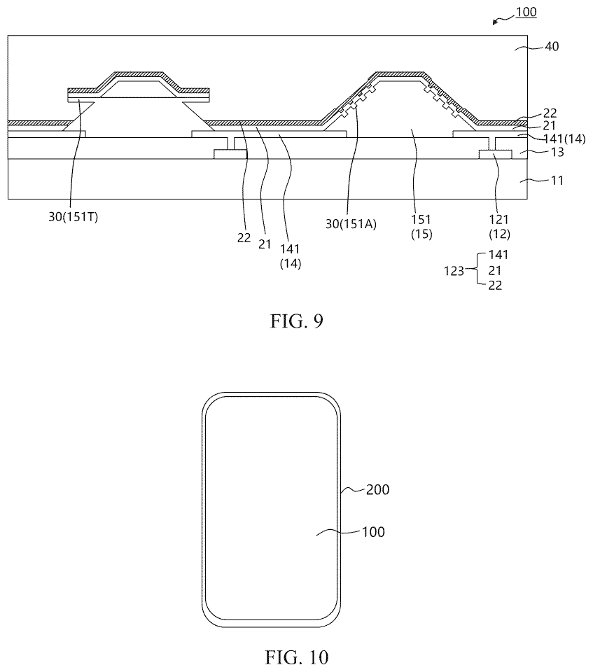

FIG. 10 is a schematic diagram of a display apparatus provided in some embodiments of the present disclosure.

In a second aspect, based on the same inventive concept, the present disclosure further provides a display apparatus 200. The display apparatus 200 includes any display panel 100 described above, or the display apparatus 200 includes the display panel 100 combining any several of the above features.

Exemplarily, the display apparatus 200 also has the beneficial effects of the display panel 100 in any one of the above-described embodiments, and the same can be understood with reference to the above explanation of the display panel 100 and will not be repeated below.

Exemplarily, the display apparatus 200 provided by the embodiment of the present disclosure can be a mobile phone shown in FIG. 10, or can be any electronic product with a display function, including but not limited to the following categories: television, laptop, desktop display, tablet computer, digital camera, smart bracelet, smart glasses, in-vehicle display, industrial control apparatus, medical display screen, touch interactive terminal, etc., which are not specifically limited in the embodiments of the present disclosure.

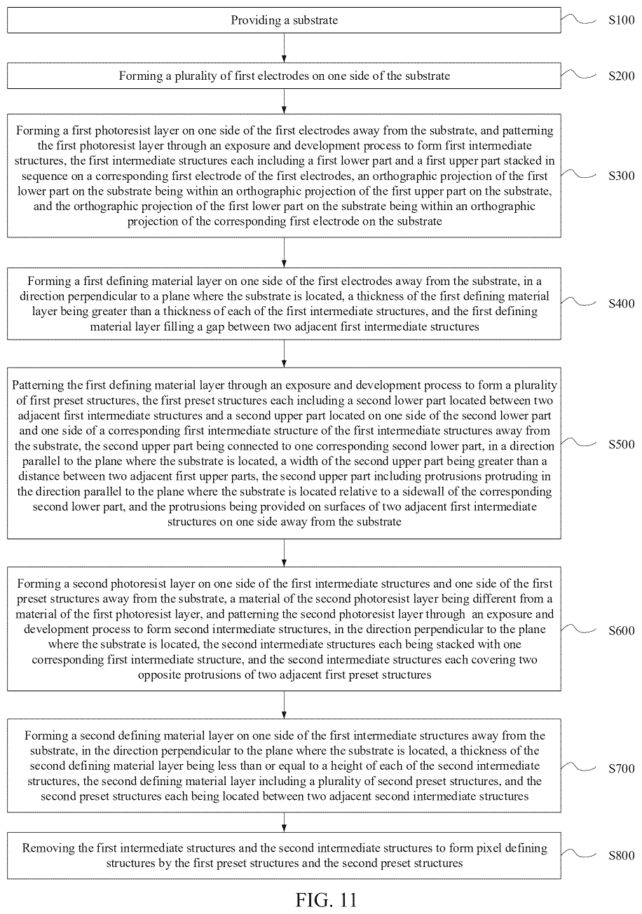

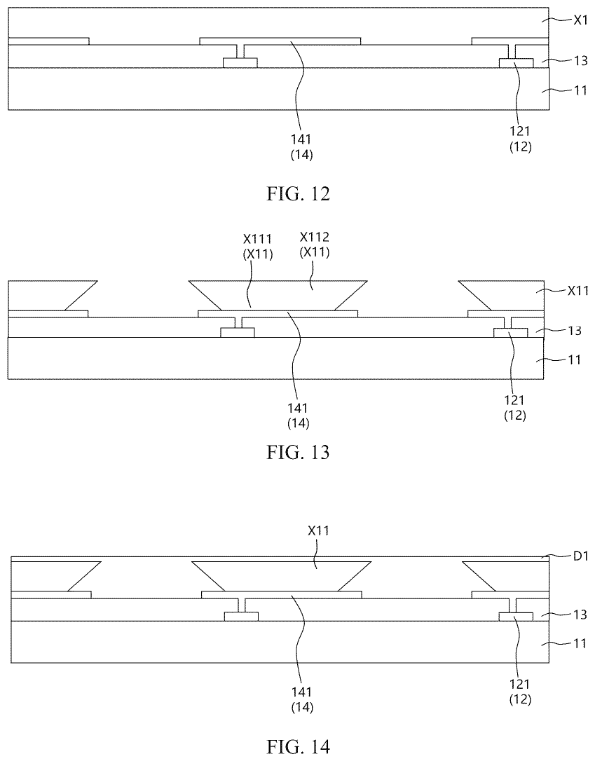

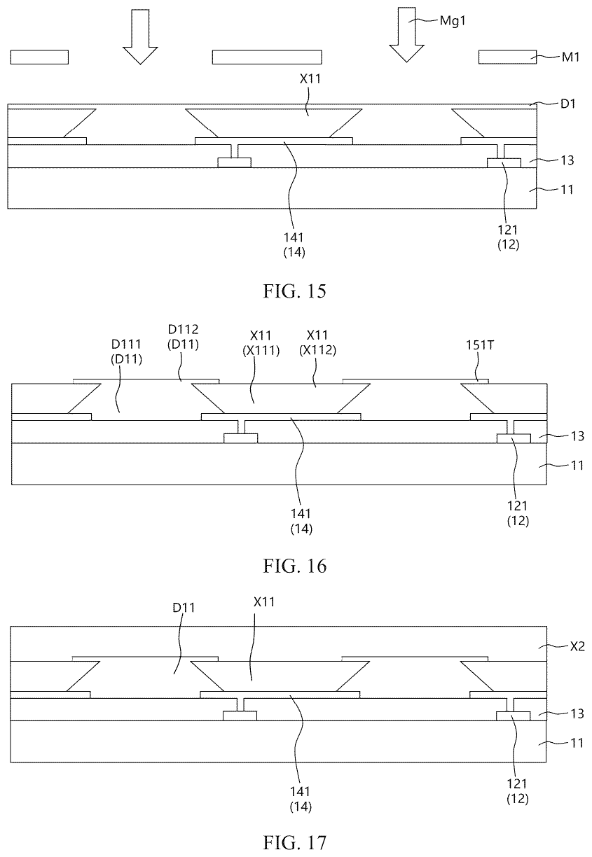

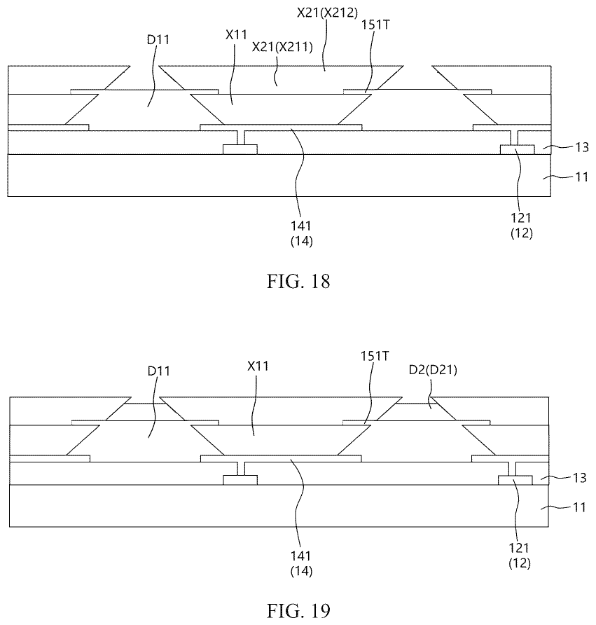

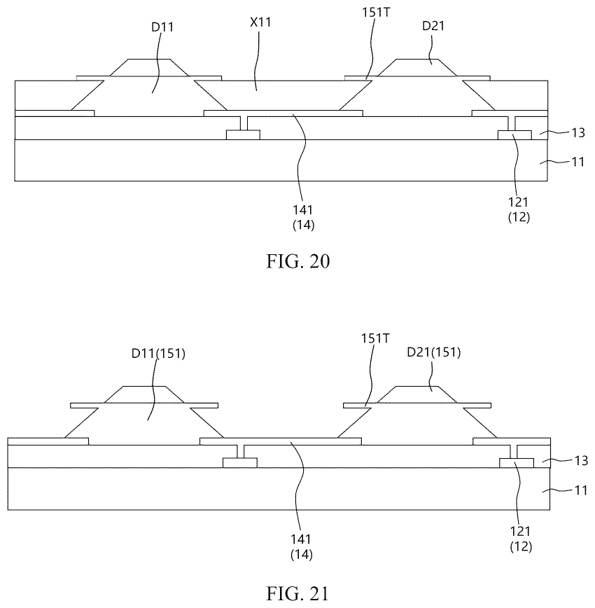

FIG. 11 is a schematic diagram of process steps of a manufacturing method of a display panel provided by some embodiments of the present disclosure. FIG. 12 is a schematic diagram of a first intermediate process of a manufacturing method of a display panel provided by some embodiments of the present disclosure. FIG. 13 is a schematic diagram of a second intermediate process of a manufacturing method of a display panel provided by some embodiments of the present disclosure. FIG. 14 is a schematic diagram of a third intermediate process of a manufacturing method of a display panel provided by some embodiments of the present disclosure. FIG. 15 is a schematic diagram of a fourth intermediate process of a manufacturing method of a display panel provided by some embodiments of the present disclosure. FIG. 16 is a schematic diagram of a fifth intermediate process of a manufacturing method of a display panel provided by some embodiments of the present disclosure. FIG. 17 is a schematic diagram of a sixth intermediate process of a manufacturing method of a display panel provided by some embodiments of the present disclosure. FIG. 18 is a schematic diagram of a seventh intermediate process of a manufacturing method of a display panel provided by some embodiments of the present disclosure. FIG. 19 is a schematic diagram of an eighth intermediate process of a manufacturing method of a display panel provided by some embodiments of the present disclosure. FIG. 20 is a schematic diagram of a ninth intermediate process of a manufacturing method of a display panel provided by some embodiments of the present disclosure. FIG. 21 is a schematic diagram of a tenth intermediate process of a manufacturing method of a display panel provided by some embodiments of the present disclosure.

In a third aspect, the present disclosure further provides a manufacturing method of a display panel. Any one of the above display panels can be manufactured by this manufacturing method of a display panel. The manufacturing method of a display panel includes: step S100, step S200, step S300, step S400, step S500, step S600, step S700, and step S800.

S100, providing a substrate.

Exemplarily, a substrate 11 is provided.

S200, forming a plurality of first electrodes on one side of the substrate.

Exemplarily, a plurality of first electrodes 141 on one side of the substrate 11 is provided.

S300, forming a first photoresist layer on one side of the first electrodes away from the substrate, and patterning the first photoresist layer through an exposure and development process to form first intermediate structures, the first intermediate structures each including a first lower part and a first upper part stacked in sequence on a corresponding first electrode of the first electrodes, an orthographic projection of the first lower part on the substrate being within an orthographic projection of the first upper part on the substrate, and the orthographic projection of the first lower part on the substrate being within an orthographic projection of the corresponding first electrode on the substrate.

Exemplarily, as shown in FIGS. 12 and 13, a first photoresist layer X1 is formed on one side of the first electrodes 141 away from the substrate 11, and the first photoresist layer X1 is patterned through an exposure and development process to form first intermediate structures X11. The first intermediate structures X11 each include a first lower part X111 and a first upper part X112 stacked in sequence on a corresponding first electrode 141 of the first electrodes 141. An orthographic projection of the first lower part X111 on the substrate 11 is within an orthographic projection of the first upper part X112 on the substrate 11, and the orthographic projection of the first lower part X111 on the substrate 11 is within an orthographic projection of the corresponding first electrode 141 on the substrate 11.

Exemplarily, the orthographic projection of the first lower part X111 on the substrate 11 is within the orthographic projection of the first upper part X112 on the substrate 11, that is, in a cross-sectional structure, the first intermediate structure X11 has a structure that is narrow at the bottom and wide at the top (for example, a cross-section is an inverted trapezoid structure).

Exemplarily, the orthographic projection of the first lower part X111 on the substrate 11 is within the orthographic projection of the corresponding first electrode 141 on the substrate 11, that is, in the direction perpendicular to the plane of the substrate 11, the first intermediate structure X11 and the first electrode 141 are stacked.

S400, forming a first defining material layer on one side of the first electrodes away from the substrate, in the direction perpendicular to the plane of the substrate, a thickness of the first defining material layer being greater than a thickness of each of the first intermediate structures, and the first defining material layer filling a gap between two adjacent first intermediate structures.

Exemplarily, as shown in FIGS. 14 and 15, a first defining material layer D1 is formed on one side of the first electrodes 141 away from the substrate 11. In the direction perpendicular to the plane of the substrate, a thickness of the first defining material layer D1 is greater than a thickness of the first intermediate structure X11, and the first defining material layer D1 fills a gap between two adjacent first intermediate structures X11.

Exemplarily, in the direction perpendicular to the plane of the substrate 11, the thickness of the first defining material layer D1 is greater than the thickness of each of the first intermediate structures X11, so that after the first defining material layer D1 is patterned in a subsequent process to form a plurality of first preset structures D11, the first preset structures D11 each include protrusions 151T protruding in a direction parallel to the plane of the substrate 11 relative to a sidewall of a corresponding second lower part D111, and the protrusions 151T each are provided on surfaces of two adjacent first intermediate structures X11 on one side away from the substrate 11.

S500, patterning the first defining material layer through an exposure and development process to form a plurality of first preset structures, the first preset structures each including a second lower part located between two adjacent first intermediate structures and a second upper part located on one side of the second lower part and one side of the two adjacent first intermediate structures away from the substrate, the second upper part being connected to one corresponding second lower part, in a direction parallel to the plane of the substrate, a width of the second upper part being greater than a distance between two adjacent first upper parts, the second upper part including protrusions protruding in the direction parallel to the plane of the substrate relative to a sidewall of the corresponding second lower part, and the protrusions being provided on surfaces of two adjacent first intermediate structures on one side away from the substrate.

Exemplarily, as shown in FIGS. 15 and 16, the first defining material layer D1 is patterned through an exposure and development process to form a plurality of first preset structures D11. The first preset structures D11 each include a second lower part D111 located between two adjacent first intermediate structures X11 and a second upper part D112 located on one side of the second lower part D111 and one side of the two adjacent first intermediate structure X11 away from the substrate 11. The second upper part D112 is connected to a corresponding second lower part D111. In the plane parallel to the plane of the substrate 11, a width of the second upper part D112 is greater than a distance between two adjacent first upper parts X112. The second upper part D112 includes protrusions 151T protruding in the direction parallel to the plane of the substrate 11 relative to a sidewall of a corresponding second lower part D111, and the protrusions 151T each are provided on surfaces of two adjacent first intermediate structures X11 on one side away from the substrate 11.

Exemplarily, as shown in FIGS. 15 and 16, when the first defining material layer D1 is a photoresist material, a first photomask M1 and light such as ultraviolet light Mg1 and the like are used to perform an exposure and development process on the first defining material layer to pattern the first defining material layer D1 to form a plurality of first preset structures D11.

Exemplarily, as shown in FIGS. 15 and 16, when the first defining material layer D1 is a non-photoresist material (for example an inorganic material), a photoresist layer is formed on a surface of the first defining material layer D1 on one side away from the substrate 11 (not shown in FIG. 15) first, then using a first photomask M1, light such as ultraviolet light Mg1 and the like to perform an exposure and development process on the photoresist layer to pattern the photoresist layer, then an etching process is used to pattern the first defining material layer D1 to form a plurality of first preset structures D11 in FIG. 16, and then the remaining photoresist layer on the surface of the first preset structures D11 on one side away from the substrate 11 is removed.

Exemplarily, the second upper part D112 includes the protrusions 151T protruding in the direction parallel to the plane of the substrate 11 relative to the sidewall of the second lower part D111, and the protrusions 151T are the blocking structures 30 in the foregoing implementations.

S600, forming a second photoresist layer on one side of the first intermediate structures and one side of the first preset structures away from the substrate, a material of the second photoresist layer being different from a material of the first photoresist layer, and patterning the second photoresist layer through an exposure and development process to form second intermediate structures, in the direction perpendicular to the plane of the substrate, the second intermediate structures each being stacked with one corresponding first intermediate structure, and the second intermediate structures each covering two opposite protrusions of two adjacent first preset structures.

Exemplarily, as shown in FIGS. 17 and 18, a second photoresist layer X2 is formed on one side of the first intermediate structures X11 and one side of the first preset structures D11 away from the substrate 11. A material of the second photoresist layer X2 is different from a material of the first photoresist layer X1. The second photoresist layer X2 is patterned through an exposure and development process to form second intermediate structures X21. In the direction perpendicular to the plane of the substrate 11, the second intermediate structures X21 each are stacked with one corresponding first intermediate structure X11, and the second intermediate structures X21 each cover two opposite protrusions 151T of two adjacent first preset structures D11.

Exemplarily, as shown in FIG. 18, the second intermediate structure X21 each include a third lower part X211 and a third upper part X212 stacked in sequence on the corresponding first intermediate structure X11. An orthographic projection of the third lower part X211 on the substrate 11 is within an orthographic projection of the third upper part X212 on the substrate 11.

Exemplarily, the orthographic projection of the third lower part X211 on the substrate 11 is within the orthographic projection of the third upper part X212 on the substrate 11, that is, in a cross-sectional structure, the second intermediate structure X21 has a structure that is narrow at the bottom and wide at the top (for example, a cross-section is an inverted trapezoid structure).

Exemplarily, the material of the second photoresist layer X2 is different from the material of the first photoresist layer X1. The material of the second photoresist layer X2 and the material of the first photoresist layer X1 respectively correspond to different developing solutions and removing solvents, so that when the second photoresist layer X2 is patterned through an exposure and development process to form the second intermediate structures X21, no damage and other impacts will be caused to the pattern of the first intermediate structures X11.

Exemplarily, the second intermediate structures X21 are prepared for the subsequent manufacturing of the second preset structures D21.

S700, forming a second defining material layer on one side of the first intermediate structures away from the substrate, in the direction perpendicular to the plane of the substrate, a thickness of the second defining material layer being less than or equal to a height of each of the second intermediate structures, the second defining material layer including a plurality of second preset structures, and the second preset structures each being located between two adjacent second intermediate structures.

Exemplarily, as shown in FIG. 19, a second defining material layer D2 is formed on one side of the first intermediate structure X11 away from the substrate 11. In the direction perpendicular to the plane of the substrate 11, a thickness of the second defining material layer D2 is less than or equal to a height of each of the second intermediate structures X21. The second defining material layer D2 includes a plurality of second preset structures D21, and the second preset structures D21 each are located between two adjacent second intermediate structures X21.

Exemplarily, in the direction perpendicular to the plane of the substrate 11, a thickness of the second defining material layer D2 is less than or equal to a height of each of the second intermediate structures X21, so that during the formation of the second defining material layer D2, the second defining material layer D2 is already patterned by the second intermediate structures X21, and there is no need to pattern the second defining material layer D2 through an exposure and development process, simplifying the manufacturing process.

Exemplarily, the first defining material layer D1 and the second defining material layer D2 can be inorganic materials, such as silicon nitride, silicon oxide, silicon oxynitride, etc, which is not a limitation, and the first defining material layer D1 and the second defining material layer D2 can also be organic materials.

S800, removing the first intermediate structures and the second intermediate structures to form pixel defining structures by the first preset structures and the second preset structures.

Exemplarily, as shown in FIGS. 20 and 21, the first intermediate structures X11 and the second intermediate structures X21 are removed. The first intermediate structures X11 and the second intermediate structures X21 can be removed with a glue solution (for example, the first intermediate structures X11 and the second intermediate structures X21 react with the glue solution, for example, the first intermediate structures X11 and the second intermediate structures X21 are dissolved in the glue solution). The first preset structures D11 and the second preset structures D21 form pixel defining structures 151.

Exemplarily, as shown in FIG. 20, the second intermediate structures X21 are removed first, and as shown in FIG. 21, then the first intermediate structures X11 are removed. The remaining first preset structures D1i and second preset structures D21 form the pixel defining structures 151. The first preset structures D1i are the first portions 15110 and the protrusions 151T in the foregoing implementations, and the second preset structures D21 are the second portions 15120 in the foregoing implementations.

Exemplarily, in some examples such as those in FIGS. 8 and 9, after forming the protrusions 151T on part of the first sidewall 151C, grooves 151A can also be formed on part of the first sidewall 151C. For instance, after step S800, the method further includes forming grooves 151A on part of the first sidewall 151C.

Exemplarily, a photoresist layer can be formed on a surface of the first sidewall 151C away from the substrate 11, and the grooves 151A can be formed through exposure, development, and etching processes.

Exemplarily, after forming a plurality of blocking structures 30 on the first sidewall 151C, the manufacturing method of a display panel may further include: forming a light-emitting common layer 21; and forming an encapsulation layer. The encapsulation layer can be a thin-film encapsulation layer. For example, the encapsulation layer includes inorganic materials and organic materials that are stacked and alternately arranged.

Exemplarily, before forming a plurality of first electrodes (before step S200), the manufacturing method of a display panel may further include: forming a plurality of driving circuits on one side of the substrate 11, the plurality of driving circuits including a plurality of thin-film transistors. The first electrodes 141 can be formed on one side of the plurality of driving circuits away from the substrate 11, and the first electrodes 141 each are electrically connected to the thin-film transistor in a corresponding driving circuit.

It should be noted that, in some examples such as those in FIGS. 4 to 7, the plurality of blocking structures 30 include a plurality of grooves 151A located on the first sidewall 151C. The photoresist layer can be formed on the surface of the first sidewall 151C away from the substrate 11, and the grooves 151A can be formed through exposure, development, and etching processes.

The technical features of the above-described embodiments can be combined arbitrarily. To make the description concise, not all possible combinations of the technical features in the above-described embodiments have been described. However, as long as there is no contradiction in the combination of these technical features, they should be considered within the scope recited in this specification.

The above-described embodiments only represent several implementations of the present disclosure. Although the description of the embodiments is relatively specific and detailed, it should not be construed as a limitation on the scope of the present disclosure. It should be pointed out that for those of ordinary skill in the art, several modifications and improvements can be made without departing from the concept of the present disclosure, and these all fall within the protection scope of the present disclosure. Therefore, the protection scope of the patent of the present disclosure shall be subject to the appended claims.

What is claimed is:

1. A display panel, comprising:
a substrate;
a pixel defining layer located on one side of the substrate, the pixel defining layer comprising pixel defining structures and a plurality of pixel openings surrounded by the pixel defining structures; and
a plurality of light-emitting devices located on the one side of the substrate, each of the light-emitting devices being at least partially located within corresponding pixel openings, each of the light-emitting devices comprising a light-emitting common layer located on one side of the pixel defining layer away from the substrate;
wherein a surface of each of the pixel defining structures comprises a first sidewall surrounding one corresponding pixel opening and a first top surface away from the substrate, the first sidewall is connected to the first top surface, and each of the pixel defining structures further comprises a plurality of blocking structures located on at least part of the first sidewall.

2. The display panel according to claim 1, wherein the plurality of blocking structures comprise at least one of a plurality of protrusions and a plurality of grooves located on the first sidewall.

3. The display panel according to claim 2, wherein the plurality of blocking structures comprise the plurality of protrusions located on the first sidewall; and
a first gap is formed between a surface of each of the protrusions close to the substrate and the first sidewall.

4. The display panel according to claim 3, wherein at the first gap, an included angle between the surface of each of the protrusions close to the substrate and the first sidewall is an acute angle; and
an included angle between the first sidewall and a bottom surface of a corresponding pixel defining structure close to the substrate is an acute angle.

5. The display panel according to claim 3, wherein a protruding direction of each of the protrusions is parallel to a plane of the substrate.

6. The display panel according to claim 3, wherein an edge of each of the protrusions comprises a first protrusion sub-edge close to one of the plurality of pixel openings, and an edge of the first sidewall comprises a first sidewall sub-edge close to the substrate and a second sidewall sub-edge connected to the first top surface; and
along a direction perpendicular to the substrate, an orthographic projection of the first protrusion sub-edge is located between an orthographic projection of a corresponding first sidewall sub-edge and an orthographic projection of a corresponding second sidewall sub-edge.

7. The display panel according to claim 3, wherein in a direction perpendicular to a plane of the substrate, each of the pixel defining structures comprises at least a first portion located on one side of the protrusions close to the substrate and a second portion located on one side of the protrusions away from the substrate, and the protrusions and the first portion are an integrally formed structure.

8. The display panel according to claim 3, wherein in a plane parallel to a plane of the substrate, each of the protrusions is a non-closed structure extending around the corresponding pixel opening.

9. The display panel according to claim 2, wherein the plurality of blocking structures comprise the plurality of grooves located on the first sidewall; and
an opening of each of the grooves faces a direction of the first sidewall away from the substrate.

10. The display panel according to claim 9, wherein in a direction perpendicular to a surface of the first sidewall, a depth of each of the grooves is a first depth, a thickness of the light-emitting common layer is a first thickness, and the first depth is less than the first thickness.

11. The display panel according to claim 10, wherein a ratio of the first depth to the first thickness is within a range from 0.5 to 0.8.

12. The display panel according to claim 9, wherein from an end of the first sidewall close to the substrate to an end of the first sidewall close to the first top surface, a width of the groove is a first width, and the first width is within a range from 200 nanometers to 500 nanometers.

13. The display panel according to claim 9, wherein each of the grooves comprises two groove sidewalls provided opposite to each other and a groove bottom wall connecting the two groove sidewalls, and the light-emitting common layer comprises a first common layer portion covering the two groove sidewalls and a second common layer portion covering the groove bottom wall; and an included angle between the first common layer portion and the second common layer portion in a direction away from the substrate is greater than 110 degrees.

14. The display panel according to claim 9, wherein the plurality of blocking structures comprise the plurality of grooves located on the first sidewall, and the plurality of grooves are arranged in sequence from an end of the first sidewall close to the substrate to an end of the first sidewall close to the first top surface; and
each of the plurality of grooves extends around a corresponding pixel opening.

15. The display panel according to claim 9, wherein the pixel defining structure comprises the plurality of grooves located on the first sidewall, an orthographic projection of each of the grooves on a plane of the first sidewall is in a block shape; and
on the first sidewall, the plurality of grooves are arranged in a staggered manner around a corresponding pixel opening.

16. The display panel according to claim 2, wherein at least part of the plurality of blocking structures comprise the protrusions located on the first sidewall and the grooves located on the first sidewall; and
the protrusions are provided on the first sidewall on at least one side of at least part of the light-emitting devices, and the grooves are provided on the first sidewall on at least one side of at least part of the light-emitting devices.

17. The display panel according to claim 16, wherein the protrusions and the grooves are provided on the first sidewall around each of at least part of the light-emitting devices, and the protrusions and the grooves are located on different sides of the light-emitting device.

18. The display panel according to claim 17, wherein the plurality of light-emitting devices comprise light-emitting devices of different colors;
at least part of the protrusions are located between adjacent light-emitting devices of different colors; and
at least part of the grooves are located between adjacent light-emitting devices of a same color.

19. A display apparatus, comprising a display panel;
wherein the display panel comprises:
a substrate;
a pixel defining layer located on one side of the substrate, the pixel defining layer comprising pixel defining structures and a plurality of pixel openings surrounded by the pixel defining structures; and
a plurality of light-emitting devices located on the one side of the substrate, each of the light-emitting devices being at least partially located within corresponding pixel openings, each of the light-emitting devices comprising a light-emitting common layer located on one side of the pixel defining layer away from the substrate;
wherein a surface of each of the pixel defining structures comprises a first sidewall surrounding one corresponding pixel opening and a first top surface away from the substrate, the first sidewall is connected to the first top surface, and each of the pixel defining structures further comprises a plurality of blocking structures located on at least part of the first sidewall.

20. A manufacturing method of a display panel, comprising steps of
S110, providing a substrate;
S120, forming a plurality of first electrodes on one side of the substrate;
S130, forming a first photoresist layer on one side of the first electrodes away from the substrate, and patterning the first photoresist layer through an exposure and development process to form first intermediate structures, the first intermediate structures each comprising a first lower part and a first upper part stacked in sequence on a corresponding first electrode of the first electrodes, an orthographic projection of the first lower part on the substrate being within an orthographic projection of the first upper part on the substrate, and the orthographic projection of the first lower part on the substrate being within an orthographic projection of the corresponding first electrode on the substrate;
S140, forming a first defining material layer on the one side of the first electrodes away from the substrate, in a direction perpendicular to a plane of the substrate, a thickness of the first defining material layer being greater than a thickness of each of the first intermediate structures, and the first defining material layer filling a gap between two adjacent first intermediate structures;
S150, patterning the first defining material layer through the exposure and development process to form a plurality of first preset structures, the first preset structures each comprising a second lower part located between two adjacent first intermediate structures and a second upper part located on one side of the second lower part and one side of a corresponding first intermediate structure of the first intermediate structures away from the substrate, the second upper part being connected to one corresponding second lower part, in a direction parallel to the plane of the substrate, a width of the second upper part being greater than a distance between two adjacent first upper parts, the second upper part comprising protrusions protruding in the direction parallel to the plane of the substrate relative to a sidewall of the corresponding second lower part, and the protrusions being provided on surfaces of the two adjacent first intermediate structures on one side away from the substrate;
S160, forming a second photoresist layer on one side of the first intermediate structures and one side of the first preset structures away from the substrate, a material of the second photoresist layer being different from a material of the first photoresist layer, and patterning the second photoresist layer through an exposure and development process to form second intermediate structures, in the direction perpendicular to the plane of the substrate, the second intermediate structures each being stacked with one corresponding first intermediate structure, and the second intermediate structures each covering two opposite protrusions of two adjacent first preset structures;
S170, forming a second defining material layer on the one side of the first intermediate structures away from the substrate, in the direction perpendicular to the plane of the substrate, a thickness of the second defining material layer being less than or equal to a height of each of the second intermediate structures, the second defining material layer comprising a plurality of second preset structures, and the second preset structures each being located between two adjacent second intermediate structures; and
S180, removing the first intermediate structures and the second intermediate structures to form pixel defining structures by the first preset structures and the second preset structures.
